(19) United States
(12) Patent Application Publication
(10) Pub. No.: US 2009/0120785 A1
(43) Pub. Date: May 14, 2009

(54) METHOD FOR FORMING METAL FILM OR STACKED LAYER INCLUDING METAL FILM WITH REDUCED SURFACE ROUGHNESS

(75) Inventors: Hui-Shen Shih, Changhua County (TW); Chun-Ming Wu, Nantou County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: UNITED MICROELECTRONICS CORP., Hsinchu (TW)

(21) Appl. No.: 12/350,971

(22) Filed: Jan. 9, 2009

Related U.S. Application Data
(63) Continuation-in-part of application No. 11/306,371, filed on Dec. 26, 2005.

(51) Int. Cl. C23C 14/34

(52) U.S. Cl. 204/192.12

(57) ABSTRACT

A method for forming a stacked layer with a reduced surface roughness that includes at least a metal film and an anti-reflection coating thereon is described. A sputtering process is conducted using a metal target to deposit a layer of metal on a substrate, wherein the DC power density over the sputtered surface of the metal target is set higher than 5 W/inch², and the layer of metal has a thickness of 4000 Å or less. A cooling step is performed, and then an anti-reflection coating is deposited on the metal film at a temperature of 300° C. or lower.

### CROSS-REFERENCE TO RELATED APPLICATION

This application is a continuation-in-part of and claims priority benefit of U.S. application Ser. No. 11/306,371, filed on Dec. 26, 2005, now pending. The entirety of the above-mentioned patent application is hereby incorporated by reference herein and made a part of this specification.

### BACKGROUND OF THE INVENTION

1. Field of the Invention

The present invention relates to an integrated circuit (IC) process. More particularly, the present invention relates to a method of forming a metal film, especially an aluminum (Al) film or an Al-alloy film, with a reduced surface roughness, and to a method of forming a stacked layer with a reduced surface roughness that includes at least a metal film and an anti-reflection coating thereon.

2. Description of the Related Art

As the linewidth of IC fabricating process is much decreased, surface roughness of deposited metal layers becomes a very important issue. If a metal film is deposited with a larger surface roughness, the accuracy of the subsequent lithography process for defining the metal film is lowered due to the off-focus effect, so that a bridging problem easily occurs to the metal pattern defined to lower the product yield.

The metal film materials widely used in ICs include aluminum (Al), and an Al film is usually deposited with sputtering. However, an Al film formed with sputtering conventionally suffers from a large surface roughness, so that the photoresist pattern and the pattern transferred to the aluminum film are incorrect lowering the product yield.

### SUMMARY OF THE INVENTION

Accordingly, this invention provides a method for forming a metal film with a reduced surface roughness.

This invention also provides a method for forming an aluminum film with a reduced surface roughness as an embodiment of the method for forming a metal film.

This invention further provides a method for forming a stacked layer with a reduced surface roughness that includes at least a metal film and an anti-reflection coating (ARC) thereon.

In the method for forming a metal film with a reduced surface roughness of this invention, a sputtering process using a metal target is conducted to deposit a layer of metal on a substrate, wherein the DC power density over the sputtered surface of the metal target is set higher than 5 W/inch², and the layer of metal has a thickness of 4000 Å or less.

In the above method, the metal film may be an Al film or an Al-alloy film containing at least one element selected from Au, Ag, Cu, In, Ta and Mo, and the sputtering process may be a DC-sputtering process or an RF plasma sputtering process. In one embodiment, the metal film is an Al film and the sputtering process is a direct current (DC) sputtering process.

In the method for forming a stacked layer with a reduced surface roughness of this invention, a metal film is formed as above, and then an anti-reflection coating is deposited on the metal film at a temperature of 300° C. or lower. Since the metal film has a reduced surface roughness, the anti-reflection coating deposited thereon can also have a reduced surface roughness. That is, the stacked layer including the metal film and the anti-reflection coating can have a reduced surface roughness.

In an embodiment of the above method, a cooling step is performed after the sputtering process but before the deposition of the anti-reflection coating. With the cooling step, the surface roughness of the stacked layer can be further reduced. The cooling step also eliminate formation of TiAl₃ due to reaction of Al and bottom Ti or Ti/TiN, so that electron migration and defects can also be reduced.

It is to be understood that both the foregoing general description and the following detailed description are exemplary, and are intended to provide further explanation of the invention as claimed.

### BRIEF DESCRIPTION OF THE DRAWINGS

FIG. 1 illustrates a process of forming a stacked layer including at least a metal film and an anti-reflection coating according to an embodiment of this invention.

FIG. 2 shows the variations of the surface roughness of a deposited aluminum film with the DC power (density) at 400° C. and 275°, respectively.

### DESCRIPTION OF THE PREFERRED EMBODIMENTS

In the preferred embodiment, the metal film is deposited with a DC-sputtering process. However, the metal film can alternatively be deposited with other sputtering process, such as an RF plasma sputtering process. Since an RF plasma sputtering process is similar to a DC-sputtering process except additionally using an RF power source for generating plasma, its description is omitted here.

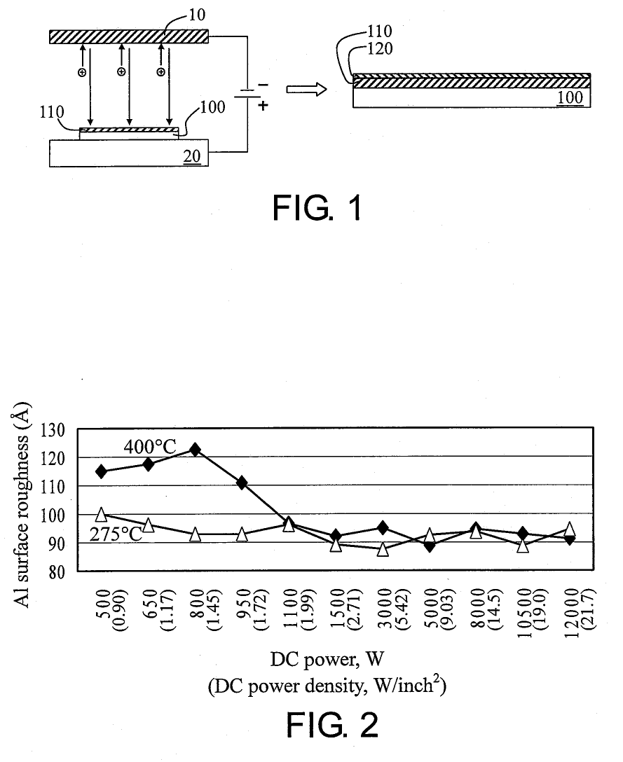

Referring to FIG. 1, a substrate 100, such as a semiconductor wafer like an 8-inch or 12-inch silicon wafer, is loaded in a DC-sputtering system like an Endura PVD System that essentially includes a metal target 10 as a cathode and an anode 20, wherein the material of the metal target 10 may be Al or an Al-alloy containing at least one element selected from gold (Au), silver (Ag), copper (Cu), indium (In), tantalum (Ta) and molybdenum (Mo), etc. When the substrate 100 is a wafer, the diameter of the metal target 10 may be larger than that of the wafer by approximately 1.5 times so that the metal can de deposited on the wafer uniformly. In addition, when the metal film to be deposited contains a highly diffusive element like Al and Cu, a barrier layer is preferably formed on the substrate 100 prior to the metal film to inhibit diffusion of the element.

The substrate 100 is placed on the anode 20, and the DC-sputtering system is filled with a low-pressure inert gas, such as argon (Ar). A high DC voltage is then applied between the anode 20 and the metal target 10 as the cathode to generate a plasma containing free electrons and positive ions, wherein the positive ions are electrically drawn to the metal target 10 as the cathode to sputter metal atoms therefrom toward the substrate 100 to form a metal film 110 thereon. In the DC-sputtering process, the DC power density over the sputtered surface of the metal target 10 is set higher than 5 Watts per square inch of target area (5 W/inch²), and the metal film 110 has a deposition thickness of 4000 Å or less. When the metal film 110 to be deposited is an Al or Al-alloy film, the deposition temperature is preferably set no lower than 100° C.

After the deposition of the metal film 110 has a deposition thickness the substrate 100 may be subject to a cooling step. The cooling step may include flowing an inert gas, such as helium or argon, onto the substrate 100. The cooling rate in the cooling step may ranges from 2° C./sec to 30° C./sec.

Referring to FIG. 1 again, an anti-reflection coating (ARC) 120 is deposited on the metal film 110 to form a stacked layer together with the metal film 110. The ARC 120 can be deposited in-situ after the metal film 110 is formed. Similarly, in a case where a barrier layer is deposited on the substrate 100 prior to the metal film 110, the barrier layer, the metal film 110 and the ARC 120 can be sequentially deposited in-situ. Then, the substrate 100 may optionally be subject to another cooling step, which may be conducted in another chamber and may be done by flowing an inert gas onto the substrate 100. The anti-reflection coating 120 is deposited at a temperature of 300° C. or lower to reduce the thermal budget and the temperature difference between the deposition and the cooling process, so as to reduce the thermal stress and prevent ARC crack in the cooling process. In addition, the material of the anti-reflection coating 120 may be Ti/TiN, TiN, TaN, ITO, Zr, AlN, Si₃N₄ or a tungsten-containing material. When the material of the ARC is Ti/TiN, the ARC 120 includes a relatively thinner titanium (Ti) layer as an adhesive layer and a relatively thicker titanium nitride (TiN) layer as a light absorption layer on the Ti layer. The Ti layer may be deposited with DC sputtering, and the TiN layer may be deposited with reactive sputtering.

FIG. 2 shows the variations of the surface roughness of a deposited aluminum film with the DC power (density) at 400° C. and 275°, respectively, wherein the values of DC power density (W/inch²) in the parentheses are calculated by dividing the values of DC power (W) by the area (inch²) of the sputtered surface of the aluminum target. The DC sputtering system used in the experiments is an Endura PVD System for 8″ wafers that is manufactured by Applied Materials Inc., wherein the area of the sputtered surface of the Al target is about 553.5 inch². The thickness of the deposited aluminum film is controlled at 3000 Å.

Based on the results shown in FIG. 2, it is confirmed that the aluminum surface roughness can be effectively reduced by setting the DC power density higher than 5 W/inch², especially when the Al-deposition temperature is higher. Since the Al film has a reduced surface roughness, the anti-reflection coating deposited thereon can also have a reduced surface roughness. That is, the stacked layer including the aluminum film and the anti-reflection coating can have a reduced surface roughness.

Moreover, with a cooling step conducted after the sputtering process of the Al film but before the deposition of the anti-reflection coating, the surface roughness of the stacked layer can be further reduced. The cooling step also eliminate formation of TiAl₃ due to reaction of Al and bottom Ti or Ti/TiN, so that electron migration and defects can also be reduced.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

What is claimed is:

1. A method of forming a stacked layer with a reduced surface roughness that includes at least a metal film and an anti-reflection coating thereon, comprising:
conducting a sputtering process using a metal target to deposit a metal film on a substrate, wherein a DC power density over a sputtered surface of the metal target is set higher than 5 W/inch², and the metal film has a thickness of 4000 Å or less;
performing a first cooling step after the sputtering process; and
depositing an anti-reflection coating on the metal film at a temperature of 300° C. or lower after the first cooling step.

2. The method of claim 1, wherein the first cooling step comprises flowing an inert gas onto the substrate.

3. The method of claim 1, wherein a cooling rate in the first cooling step ranges from 2° C./sec to 30° C./sec.

4. The method of claim 1, wherein the metal film and the anti-reflection coating are deposited in-situ.

5. The method of claim 1, further comprising a step of depositing a barrier layer on the substrate before the metal film is deposited.

6. The method of claim 5, wherein the barrier layer, the metal film and the anti-reflection coating are sequentially deposited in-situ.

7. The method of claim 1, further comprising a second cooling step after the anti-reflection coating is deposited.

8. The method of claim 7, wherein the second cooling step comprises flowing an inert gas onto the substrate.

9. The method of claim 1, wherein the sputtering process is a DC-sputtering process or an RF plasma sputtering process.

10. The method of claim 1, wherein the metal film is an Al film or an Al-alloy film containing at least one element selected from Au, Ag, Cu, In, Ta and Mo.

11. The method of claim 10, wherein the sputtering process is conducted at a temperature no lower than 100° C.

12. The method of claim 1, wherein the anti-reflection coating comprises Ti/TiN, TiN, TaN, ITO, Zr, AlN, Si₃N₄ or a tungsten-containing material.

13. The method of claim 1, wherein the metal film is an Al film and the sputtering process is a DC-sputtering process.

14. The method of claim 1, wherein the substrate is an 8-inch or 12-inch wafer.
